(19) United States
(12) Patent Application Publication
(10) Pub. No.: US 2015/0359101 A1
(43) Pub. Date: Dec. 10, 2015

(54) ELECTRONIC UNIT WITH A SEMICONDUCTOR LIGHTING DEVICE IN A PROTECTED ARRANGEMENT ON A CARRIER

(71) Applicant: HELLA KGAA HUECK & CO., Lippstadt (DE)

(72) Inventor: Heinrich Schäfer, Bad Wünnenberg (DE)

(21) Appl. No.: 14/761,248

(22) PCT Filed: Feb. 10, 2014
(86) PCT No.: PCT/EP2014/052511

§ 371 Date: Jul. 15, 2015

(30) Foreign Application Priority Data
Feb. 12, 2013 (DE) 10 2013 101 341.4

(51) Int. Cl. H05K 1/18; F21S 8/10

(52) U.S. Cl. CPC H05K 1/181; F21S 48/212; F21S 48/1109; H05K 2201/10106; H05K 2201/2027

(57) ABSTRACT

An electronic unit for a lighting device in a motor vehicle. The electronic unit may include at least one touch-sensitive part which is mounted onto a carrier and which surpasses at least partly beyond the surface of the carrier. In order to protect the touch-sensitive part of any direct physical contact by means of further objects, at least one guiding element may be mounted onto the carrier adjacent to the touch-sensitive part. The shape and size of the guiding element may be designed in such a way, that the touch-sensitive part is protected against any physical contact to further objects by the guiding element.

### CROSS REFERENCE

This application claims priority to PCT Application No. PCT/EP2014/052511 filed Feb. 10, 2014, which itself claims priority to German Application No. 10 2013 101341.4, filed Feb. 12, 2013, the entirety of both of which are hereby incorporated by reference.

### FIELD OF TECHNOLOGY

The present invention relates to an electronic unit, in particular for a lighting device in a motor vehicle, with at least one touch-sensitive part, which is mounted onto a carrier and which protrudes at least partly beyond the surface of the carrier.

### BACKGROUND

For example DE 10 2007 048 841 A1 depicts an electronic unit, which is intended to be mounted into a door mirror of a motor vehicle, in order to e.g. fulfill the function of a direction indicator. The electronic unit consists of touch-sensitive parts in form of LED lighting devices, and it is to be prevented in general, that the LED lighting devices are touched by other objects, particularly during the mounting. Especially when the LED lighting devices are made without any protective housing, a simple touch of the LED lighting devices by means of e.g. light guiding elements, which have to be mounted later on, could e.g. lead to damages of the LED lighting devices.

EP 2 277 741 presents another arrangement of LED lights in a lighting device of a motor vehicle, which are part of an electronic unit. The LED lights are mounted onto a carrier in such a way that they protrude freely over its surface, and during the mounting of the electronic unit it is possible, that the LED lights are touched by the light guiding element that is to be mounted. The LED lights can thus be damaged.

### SUMMARY OF THE INVENTION

The objective of the invention is to develop an electronic unit in particular for a lighting device of a motor vehicle in such a way, that touch-sensitive parts on a carrier of the electronic unit cannot touch or get in any physical contact with other objects.

This invention includes the technical teaching, that at least one guiding element is mounted onto the carrier adjacent to the touch-sensitive unit, whereby the shape and size of the guiding element is designed in such a way, that the touch-sensitive unit is protected against any physical contact to further objects by the guiding element.

The invention is based on the idea, that the touch-sensitive part is protected by a guiding element which is arranged directly adjacent to the touch-sensitive part, that other objects which could come into close vicinity of the touch-sensitive part, e.g. during the mounting or any other handling of the electronic unit, will be guided past or over the touch-sensitive part. As a result, a collision of the further objects with the touch-sensitive part is prevented, since it is always the guiding element that will first touch the further object before the further object would get in physical contact with the touch-sensitive part.

An adjacent arrangement of the guiding element and of the touch-sensitive part is already achieved when the guiding element is arranged onto the carrier at least within the vicinity of the touch-sensitive unit. The guiding element may even touch the touch-sensitive part or at least partially surround it. In any case, an adjacent arrangement is achieved, when the guiding element is able to prevent any direct contact of the touch-sensitive part to any further objects by means of its shape and size. In the most ideal situation, the guiding element can be arranged in such a way adjacent to the touch-sensitive part on the carrier, that the guiding element is located e.g. directly next to the touch-sensitive part. It is also possible that the guiding element is arranged round about the touch-sensitive part, without being a part of the touch-sensitive part itself.

It is e.g. possible that the guiding element surpasses beyond the top of the touch-sensitive part in its construction height above the surface of the carrier. Herein it may be sufficient if the height of the guiding element surpasses at least a little bit beyond the height of the touch-sensitive part above the carrier. The further object may e.g. be a light guiding element, which is placed onto the electronic unit by hand, by means of some device or with the aid of a machine. During its positioning, it is possible that tolerances within the lateral movements occur, which would have the effect that the further unit would be moved into the direction of the touch-sensitive unit. If the guiding element is slightly higher than the touch-sensitive unit, a touching or direct contact of the touch-sensitive part by means of the light guiding element is prevented right away.

If objects are added as further parts of the electronic unit, it is possible to observe a mounting direction, and the guiding element is located in front of the arrangement of the touch-sensitive part when viewed in the mounting direction. If the further object is now moved towards the unit, the first physical contact will always be with the guiding element before any contact with the touch-sensitive part is possible.

The touch-sensitive part can e.g. be made by a semiconductor lighting device. Semiconductor lighting devices are preferably created by SMD-mounted LEDs, which often do not consist of an own housing. The semiconductor emitter thus lies in the open, and a simple touching by means of a further object can lead to the damaging of the semiconductor emitter.

The electronic unit can e.g. consist of an electronic circuit board, and the carrier that is holding the touch-sensitive part and the guiding element can be formed by means of the electronic circuit board. The electronic circuit board can be arranged on a base body, in particular if this is made of a flexible circuit substrate.

Another advantage would be that the guiding element itself could fulfill an electronic function of the electronic unit. It is e.g. possible that the guiding element is a coil, a capacitor, a resistor, a fuse, a semiconductor element, an inductor or e.g. a magnetic core or the like. The guiding element advantageously features a cubical or cylindrical shape and forms a solid element that is mounted onto the carrier with its shape and size being inflexible.

The guiding element can be designed in such a way, that it forms a guiding and/or a limit stop for the further object. The further object can form e.g. a part, which can also be mounted or soldered onto the carrier or relative to the carrier as a portion of the electronic unit. Hereby, the guiding element can serve the purpose to e.g. adjust a certain relative position of the further object with regards to the touch-sensitive unit, in particular when the guiding element serves e.g. as a limit stop. The limit stop can hereby function perpendicular to the surface of the carrier, but it is also possible that the limit stop function is operating e.g. within the mounting direction of the further object, and the mounting direction can e.g. be aligned in transverse direction to the expansion direction of the touch-sensitive parts above the surface of the carrier. It is further advantageous if the guiding element is designed in such a way, that it provides a mounting direction for the further object. One or more guiding elements can be arranged onto the carrier in particular relative to the touch-sensitive part and in such a way, that the further object can only be mounted to the electronic unit from one direction, which is defined by means of the guiding element. In connection with this mounting, the guiding elements are further designed in such a way, that any physical contact of the touch-sensitive part by the further object is equally prevented.

It is also advantageous, that the touch-sensitive part and/or the guiding element are formed as respective SMD-units and that they are mounted onto the surface of the carrier. The so-called surface-mounted-devices are elements that are mounted and attached onto the surface of an electronic circuit board, in particular by means of soldering. The retaining arrangement of the SMD-elements on the electronic circuit board is already accomplished by means of the electronic contacting itself, which is generally formed by means of the solder.

### BRIEF DESCRIPTION OF THE DRAWINGS

Reference is now made more particularly to the drawings, which illustrate the best presently known mode of carrying out the invention and wherein similar reference characters indicate the same parts throughout the views.

FIG. 1 is an embodiment of an electronic unit with a touch-sensitive part in form of a semiconductor lighting device.

FIG. 2 is a side view of the electronic unit according to FIG. 1.

FIG. 3 is a further embodiment of an electronic unit in a perspective view.

FIG. 4 is a side view of the embodiment of the electronic unit according to FIG. 3.

### DETAILED DESCRIPTION OF THE DRAWINGS

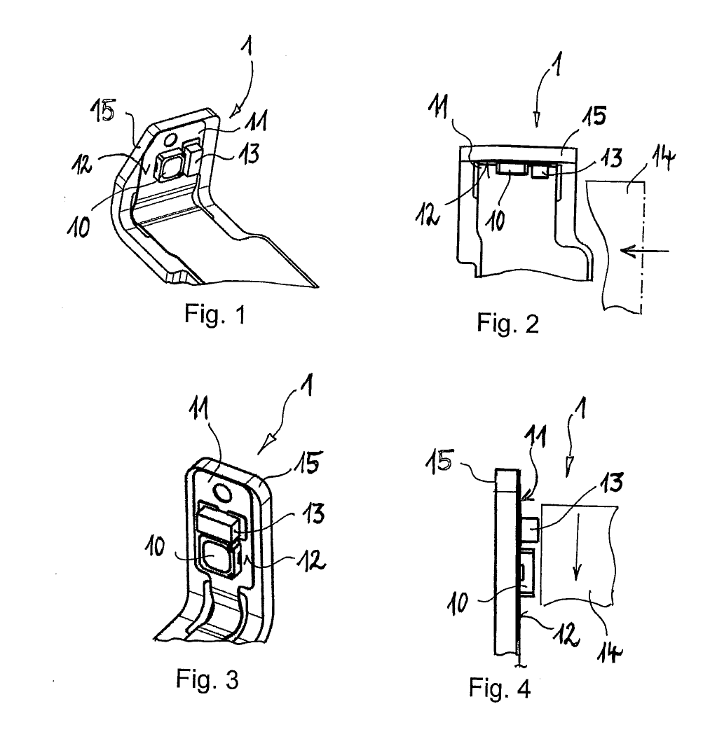

The FIGS. 1 and 2 depict a first embodiment of an electronic unit 1, which can e.g. be used in a lighting device of a motor vehicle. Unit 1 consists of a touch-sensitive part 10, which is e.g. made in form of a semiconductor lighting device 10. Semiconductor lighting device 10 is mounted onto carrier 11, which is e.g. designed as a flexible circuit substrate and carrier 11 is mounted onto a base body 15, which is made e.g. of an angled aluminum component, in order to accomplish a heat dissipation of semiconductor lighting device 10.

Adjacent to touch-sensitive part 10, a guiding element 13 is depicted, which features a greater height above surface 12 of carrier 11 than that of touch-sensitive part 10, as can be seen in FIG. 2. Furthermore, a further object 14 is depicted, which could be e.g. a light guiding element. Further object 14 is guided towards unit 1 from a mounting direction, and the mounting direction is illustrated by means of an arrow. The embodiment hereby depicts guiding element 13, which is located in front of the position where touch-sensitive part 10 is mounted onto carrier 11, when viewed in the mounting direction of the further object 14. If further object 14 is e.g. guided towards unit 1 with a tolerance in its lateral movement, guiding element 13 effectively prevents that the further object 14 can get into direct contact with the touch-sensitive part 10. If object 14 is designed in form of a light guiding element, touch-sensitive part 10 can be a semiconductor lighting device, which couples light into light guiding element 14.

FIGS. 3 and 4 depict a further embodiment of the electronic unit 1 with a carrier 11 in form of a flexible circuit substrate, which is mounted on an inflexible base body 15. The arranged position of touch-sensitive part 10 on surface 12 of carrier 11 is below a guiding element 13, and as it can be seen in FIG. 4, if a further object 14 is moved from a mounting direction towards the unit according to the depicted arrow, the guiding element 13, which is arranged above touch-sensitive part 10, prevents a direct contact of further object 14 with the touch-sensitive part 10. Touch-sensitive part 10 can also be made in form of a semiconductor lighting device 10 according to this embodiment, and the further object 14 can be a light guiding element. The adjacent arrangement of guiding element 13 towards touch-sensitive part 10 features a gap, which is at least smaller than the overall height of the touch-sensitive part 10 or of guiding element 13 above surface 12 of carrier 11. Both, the touch-sensitive part 10 as well as guiding element 13 are designed as SMD-elements, whereby guiding element 13 can also perform an electronic function within the electronic unit 1.

The invention is not limited in its design to the presently described preferred embodiments. Rather, a number of variations that make use of the depicted solution are possible, even if they feature fundamentally different designs. All characteristics and/or advantages that can be derived from the claims, the descriptions or the drawings, including constructive details, spatial arrangements and procedural steps can be relevant to the invention, both individually as well as in virtually any combination.

### LIST OF REFERENCE SIGNS

1 Electronic unit
10 Touch-sensitive part, semiconductor lighting device
11 Carrier, electronic circuit board
12 Surface of the carrier
13 Guiding element
14 Further object, light guiding element
15 Base body

1. An electronic unit for a lighting device in a motor vehicle, said electronic unit comprising:
a carrier;
at least one touch-sensitive part mounted onto the carrier and which extends at least partly beyond a surface of the carrier, and
at least one guiding element mounted onto the carrier adjacent to the touch-sensitive part,
wherein a shape and size of the guiding element such that that the touch-sensitive part is protected against any physical contact from one or more further objects by the guiding element.

2. The electronic unit according to claim 1, wherein the guiding element surpasses the touch-sensitive part in its height beyond the surface of the carrier.

3. The electronic unit according to claim 1 wherein the touch-sensitive part includes a semiconductor lighting device.

4. The electronic unit according to claim 1 wherein the carrier includes an electronic circuit board.

5. The electronic unit according to claim 1 wherein the guiding element fulfills an electronic function of the electronic unit.

6. The electronic unit according to claim 1 wherein the guiding element forms at least one of a guiding and a limit stop for the further object.

7. The electronic unit according to claim 1 wherein the guiding element is created in such a way, that a mounting direction for the further object is predefined by means of it.

8. The electronic unit according to claim 1 wherein at least one of the touch-sensitive part and the guiding element is arranged in form of a SMD element and that it is mounted onto the surface of the carrier.
